(19) United States
(12) Patent Application Publication
(10) Pub. No.: US 2008/0133989 A1
(43) Pub. Date: Jun. 5, 2008

(54) Method And Apparatus For Scan Chain Circuit AC Test

(75) Inventors: Atsushi Hayashi, Kanagawa (JP); Chiaki Takano, Austin, TX (US); Noriyuki Oshima, Santa Clara, CA (US); Takeshi Inoue, Kanagawa (JP); Hiroki Kihara, Kanagawa (JP); Yoichi Nishino, Austin, TX (US)

Correspondence Address: KAPLAN GILMAN GIBSON & DERNIER L.L.P., 900 ROUTE 9 NORTH, WOODBRIDGE, NJ, 07095, US

(73) Assignee: Sony Computer Entertainment Inc., Tokyo (JP)

(21) Appl. No.: 11/566,819

(22) Filed: Dec. 5, 2006

(51) Int. Cl. G01R 31/3185

(52) U.S. Cl. 714/726

(57) ABSTRACT

Methods and apparatus for dynamically (AC) testing a target circuit within a main circuit include: providing respective sets of input latches from among a plurality of latches of the main circuit; reconfiguring connections of at least some of the input latches from normal connections within the main circuit such that each set of input latches is connected in series and directs an input bit stream from an associated source node into an associated input node of the target circuit; scanning a plurality of sets of input bits into the respective sets of input latches such that each latch of each set of input latches contains a respective bit of an associated one of the sets of input bits; and scanning each of the sets of input bits serially into the respective input nodes of the target circuit at a sufficiently high frequency to dynamically test the target circuit.

### BACKGROUND OF THE INVENTION

The present invention relates to systems and methods for AC testing of a target circuit.

In general, testing a target circuit, such as an integrated circuit (IC), prior to packaging may reveal problems associated with the individual ICs and also with the IC fabrication process preceding the packaging step. Testing an IC after packaging may reveal problems arising from the packaging process steps, such as die attachment, wire bonding, among other steps.

So called scan chain testing techniques may be employed for testing IC circuits before and/or after packaging. Existing scan chain test operations for DC testing include scanning a known sequence of bits into a series of respective latches (flip flops) within the IC circuit. The latches are selected to direct the scanned bits to the input(s) of the target circuit, such as combinational logic, Static Random Access Memory (SRAM), etc. The target circuit is provided with a significant amount of time to let the input sequence of bits settle at the input(s) and outputs of the gates, memory cells, etc., such that test output bits are produced in response to the input bits. In other words, no dynamic testing is conducted. The output bits are directed to a selected series of output latches of the IC. Commands are then issued to scan the test output bits from the output latches, and the output bits are compared to a known template to determine whether the target circuit is operational.

Notably, the input latches and output latches are typically already part of the IC and, under normal operating modes, perform functions that permit the IC to operate. The testing designer, however, selects the input and output latches from among the latches of the IC to be used in the scan chain testing process. Selector circuits may be employed to switch the input/output connections of the selected latches between normal operating modes and the scan chain testing mode. Since the DC scan chain testing process does not perform dynamic (AC) testing, virtually any of the existing latches of the IC may be selected as input/output latches for the scan chain test process no matter where (how far) they may be located relative to the inputs/output of the target circuit, the impedances of the interconnections, or potential sources of electromagnetic interference.

Existing systems for AC testing may also involve selecting input and output latches from among existing latches of the IC to be used in an AC testing process. However, since a dynamic test is desired, the input bits to the target circuit must be rapidly provided in order to exercise the target circuit in ways that may uncover defects, such as input/output set up times, propagation delays, impedance characteristics, electromagnetic interference sources, etc. Thus, AC testing techniques typically use a CPU (Central Processing Unit) external to the target circuit to drive data into and out of selected input/output latches adjacent to the target circuit. Generally, the CPU is coupled to respective input and output connections for a portion of a circuit being tested which are generally within a limited, localized region of the test circuit. However, it is cumbersome and complex to connect an external CPU in this manner to all portions of a circuit for which testing is sought.

Accordingly, it would be desirable to conduct AC testing of circuits without employing an external CPU and without being restricted to a limited area within a circuit of interest.

### SUMMARY OF THE INVENTION

The present invention relates to a system and method providing a scan chain for testing a circuit for AC testing of a target circuit (such as combinational logic). According to one or more aspects of the invention, input scan data is scanned into a plurality of series of registers at a relatively low clock speed, in what is referred to herein as a “scan mode”. Thereafter, a “test mode” is entered during which a plurality of streams of data are rapidly delivered to the target, at a rate that will test the AC operation of the target circuit. While still in the test mode, a plurality of streams of test output data are rapidly delivered to respective parallel series of registers located on the output side of the target. Thereafter, operation shifts back to the scan mode from the test mode so that the test output data may be scanned out of the series of registers on the output side of the target. According to various embodiments of the invention, an array, or effective array, of latches is operative to rapidly transmit plural parallel bit streams to the target, which in turn, provides a rapid output of parallel bit streams to respective parallel sequences of latches. In this manner, the invention provides a plurality of different input data samples and a corresponding number of output test data samples within a single test operation. Thus, the target may be more fully exercised than in prior art scan test systems. Among the aspects of the invention is the proper selection of the input and output latches for delivering data to the target and receiving data from the target.

Methods and apparatus for dynamically (AC) testing a target circuit within a main circuit include: providing respective sets of input latches from among a plurality of latches of the main circuit; reconfiguring connections of at least some of the input latches from normal connections within the main circuit such that each set of input latches is connected in series and directs an input bit stream from an associated source node into an associated input node of the target circuit; scanning a plurality of sets of input bits into the respective sets of input latches such that each latch of each set of input latches contains a respective bit of an associated one of the sets of input bits; and scanning each of the sets of input bits serially into the respective input nodes of the target circuit at a sufficiently high frequency to dynamically test the target circuit.

The methods and apparatus may further provide for selecting the respective sets of input latches from among the plurality of latches of the main circuit. Preferably, the selection of the respective sets of input latches includes ensuring that at least one of: (i) interconnections between adjacent input latches, and (ii) interconnections between the respective sets of input latches and the respective input nodes, are capable of transmitting the sets of input bits serially into the respective input nodes of the target circuit at the sufficiently high frequency without substantially distorting the input bits and timing thereof. For example, the selection may ensure that interconnections between adjacent input latches are relatively short such that transmitting the input bits serially into the respective input nodes of the target circuit does not result in substantial distortion thereof.

The methods and apparatus may further provide for: providing respective sets of output latches from among the plurality of latches of the main circuit; reconfiguring connections of at least some of the output latches from normal connections within the main circuit such that each set of output latches directs a set of output bits, responsive to an associated one of the sets of input bits, from an associated output node of the target circuit; scanning each of the sets of output bits serially from the respective output nodes of the target circuit into the respective sets of output latches at the sufficiently high frequency such that each latch of each set of output latches contains a respective bit of an associated one of the sets of output bits; and scanning the sets of output bits from the respective sets of output latches.

Thus, the sets of output bits may be compared with expected sets of output bits to determine whether the target circuit is operational.

The methods and apparatus may further provide for selecting the respective sets of output latches from among the plurality of latches of the main circuit. Preferably, the selection of the respective sets of output latches includes ensuring that at least one of: (i) interconnections between adjacent output latches, and (ii) interconnections between the respective sets of output latches and the respective output nodes, are capable of transmitting the sets of output bits serially out of the respective output nodes of the target circuit at the sufficiently high frequency without substantially distorting the output bits and timing thereof. For example, the selection of the respective sets of output latches may include ensuring that interconnections between adjacent output latches are relatively short such that transmitting the output bits serially from the respective output nodes of the target circuit does not result in substantial distortion thereof.

The methods and apparatus may further provide for feeding back and re-scanning the plurality of sets of input bits back into the respective sets of input latches; and re-scanning each of the sets of input bits serially into the respective input nodes of the target circuit at the sufficiently high frequency to repeat the dynamic test of the target circuit. Preferably, the feeding back and re-scanning of the plurality of sets of input bits back into the respective sets of input latches is conducted at the sufficiently high frequency.

The scanning the plurality of sets of input bits into the respective sets of input latches may be performed at a first clock frequency, while the scanning of each of the sets of input bits serially into the respective input nodes of the target circuit may be conducted at a second frequency, where the first frequency is lower than the second frequency.

By way of example, the target circuit may include combinational digital logic gates, one or more digital memory arrays, etc.

In accordance with one or more further embodiments of the present invention, methods and apparatus for dynamically (AC) testing a target circuit within a main circuit may include: providing respective sets of input latches from among a plurality of latches of the main circuit; reconfiguring connections of at least some of the input latches from normal connections within the main circuit such that each set of input latches is connected in series and directs an input bit stream from an associated source node into an associated input node of the target circuit; scanning a plurality of sets of input bits from a first memory into the respective sets of input latches such that each latch of each set of input latches contains a respective bit of an associated one of the sets of input bits; and scanning each of the sets of input bits serially into the respective input nodes of the target circuit at a sufficiently high frequency to dynamically test the target circuit.

The methods and apparatus may further provide for: storing a plurality of different sets of input bits for at least one of the input nodes of the target circuit in the first memory; scanning the different sets of input bits from the first memory into an associated one of the sets of input latches; and scanning the different sets of input bits serially into the at least one input node of the target circuit at a sufficiently high frequency to dynamically test the target circuit using the different sets of input bits.

The methods and apparatus may further provide for: providing respective sets of output latches from among the plurality of latches of the main circuit; reconfiguring connections of at least some of the output latches from normal connections within the main circuit such that each set of output latches directs a set of output bits, responsive to an associated one of the sets of input bits, from an associated output node of the target circuit; scanning each of the sets of output bits serially from the respective output nodes of the target circuit into the respective sets of output latches at the sufficiently high frequency such that each latch of each set of output latches contains a respective bit of an associated one of the sets of output bits; and scanning the sets of output bits from the respective sets of output latches into a second memory.

The methods and apparatus may further provide for: scanning respective sets of output bits, each responsive to an associated one of the sets of input bits, from the output nodes into a second memory; and comparing the sets of output bits with expected sets of output bits to determine whether the target circuit is operational.

In accordance with one or more further embodiments of the present invention, methods and apparatus for dynamically (AC) testing target circuits may provide for: generating test output data within at least two target circuits in response to test input data; using the test output data from a first of said target circuits as test input data to a second of said target circuits; and using the test output data of a second of said target circuits as test input data to the first target circuit.

The first and second target circuits may be respective data memories. The two memories may be operable to transmit receive the test input data and transmit the test output data concurrently.

In accordance with one or more further embodiments of the present invention, an apparatus for dynamically (AC) testing target circuits may include: a data flow controller operable to place the apparatus in an AC test mode; at least two target circuits operable to generate test output data in response to test input data; a first target data path operable to: (i) receive test output data of a first of said target circuits, and (ii) transmit the test output data from the first target circuit as test input data to a second of said target circuits; a second target data path operable to: (i) receive test output data of the second target circuit, and (ii) transmit the test output data of the second target circuit as test input data to the first target circuit; and at least two memories operable to transmit control data to the two target circuits, respectively.

In accordance with one or more further embodiments of the present invention, a method may include: entering a scan mode by a test circuit within an integrated circuit; scanning test input data into an input circuit of the test circuit; entering an AC test mode by the test circuit; directing a plurality of streams of the test input data toward a target by the test circuit; generating test output data by the target; transmitting test output data from the target to an output circuit; transitioning from the AC test mode to the scan mode by the test circuit; and scanning the test output data out of the output circuit.

In accordance with one or more further embodiments of the present invention, an integrated circuit may include: a data flow controller operable to place a test circuit within the integrated circuit in a scan mode; an input circuit within the test circuit operable to: receive test input data in accordance with the scan mode, and transmit a plurality of streams of the test input data out of the input circuit, wherein the data flow controller is operable to place the test circuit in an AC test mode prior to the transmitting step; a target operable to: receive the plurality of streams of input data, generate test output data, and transmit the test output data out of the target; and an output circuit operable to: receive the test output data from the target, and scan the test output data out of the output circuit, wherein the data flow controller is operable to transition the test circuit from the AC test mode to the scan mode before the scanning step.

In accordance with one or more further embodiments of the present invention, a test circuit may include: a first memory operable to store test input data; an input circuit operable to: receive the test input data from the first memory, and transmit a plurality of streams of the test input data out of the input circuit; at least one target operable to: receive the streams of test input data; generate test output data based on the test input data, and transmit the test output data out of the target;

an output circuit operable to: receive the test output data from the target, and transmit the test output data out of the output circuit; and a second memory operable to: receive the test output data from the output circuit, and store the test output data, wherein the input circuit comprises a plurality of data-latch scan chains disposed between the first memory and the target.

In accordance with one of more further embodiments of the present invention, a method may include: entering a scan mode by a test circuit; scanning test input data from a first memory into an input circuit of the test circuit; entering an AC test mode by the test circuit; directing a plurality of streams of the test input data toward at least one target; generating test output data by the at least one target in response to the test input data; transmitting the test output data from the at least one target to an output circuit; transitioning from the AC test mode to the scan mode by the test circuit; and scanning the output test data from the output circuit into a second memory.

Other aspects, features, advantages, etc. will become apparent to one skilled in the art when the description of the preferred embodiments of the invention herein is taken in conjunction with the accompanying drawings.

### BRIEF DESCRIPTION OF THE DRAWINGS

For the purposes of illustrating the various aspects of the invention, there are shown in the drawings forms that are presently preferred, it being understood, however, that the invention is not limited to the precise arrangements and instrumentalities shown.

FIG. 1 is a block diagram of a circuit for AC testing a target in accordance with one or more embodiments of the present invention;

FIG. 2A is a block diagram showing an input portion of the circuit of FIG. 1 in greater detail, in accordance with one or more embodiments of the present invention;

FIG. 2B is a block diagram showing a latch of the input circuit of FIG. 2A in greater detail, in accordance with one or more embodiments of the present invention;

FIG. 2C is a block diagram showing a latch of the input circuit of FIG. 2A in greater detail; in accordance with one or more embodiments of the present invention;

FIG. 3 is a timing diagram showing the timing of signals active within the circuit of FIG. 1, in accordance with one or more embodiments of the present invention;

FIG. 4A is a block diagram showing an output portion of the circuit of FIG. 1 in greater detail, in accordance with one or more embodiments of the present invention;

FIG. 4B is a block diagram showing a latch of the output circuit of FIG. 4A in greater detail, in accordance with one or more embodiments of the present invention;

FIG. 5 is a block diagram of a circuit for AC testing a target in accordance with one or more alternative embodiments of the present invention;

FIG. 6 is a block diagram of a circuit for AC testing a target in accordance with one or more alternative embodiments of the present invention;

FIG. 7 is a block diagram of a circuit for AC testing one or more targets in accordance with one or more alternative embodiments of the present invention;

FIG. 8 is a block diagram of a circuit for AC testing one or more targets in accordance with one or more alternative embodiments of the present invention; and

FIG. 9 is a block diagram of a circuit for AC testing one or more targets in accordance with one or more alternative embodiments of the present invention.

### DETAILED DESCRIPTION OF THE PREFERRED EMBODIMENTS

Herein, the term “DC testing” generally corresponds to circuit testing which tests the steady state response of a target circuit, or simply “target.” The target may be initially in a stable condition, then receive test input data, and then generate test output data, based on logical operations and/or on memory location accesses, by the target. In DC testing, the target is generally permitted to reach a steady-state condition and to then allow test output data to be extracted therefrom. The target circuit is provided with a significant amount of time to let the input sequence of bits settle at the input(s) and outputs of the gates, memory cells, etc., such that test output bits are produced in response to the input bits. In other words, no dynamic testing is conducted.

Herein, the term “AC testing” generally corresponds to circuit testing in which the dynamic response of a target is tested. The target may initially be in a stable condition. Thereafter, one or more streams of data bits may be transmitted to the target at a relatively rapid rate, generally corresponding to the conditions the target would experience during normal operation thereof within an integrated circuit. In AC testing, the target is generally not given extra time to guarantee that all regions of the target stabilize before sending additional data and/or scanning output data from the target. Indeed, as a dynamic test is desired, the input bits to the target circuit must be rapidly provided in order to exercise the target circuit in ways that may uncover defects, such as input/output set up times, propagation delays, impedance characteristics, electromagnetic interference sources, etc. In this manner, the real-time, dynamic characteristics of the target, such as race conditions, etc., among other characteristics, may be evaluated when employing AC testing techniques.

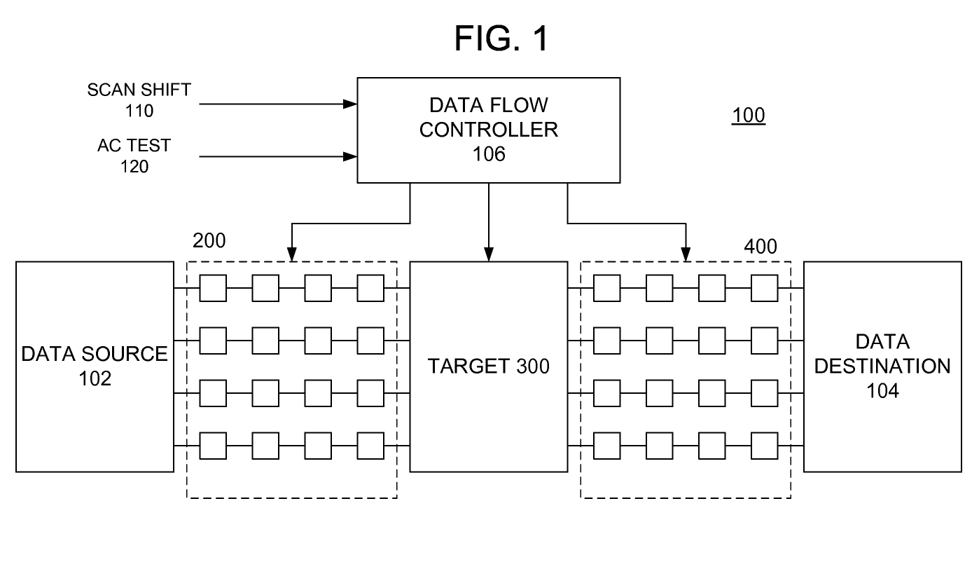

FIG. 1 is a block diagram of a circuit 100 for AC testing a target 300 in accordance with one or more embodiments of the present invention. For the purposes of this discussion, it is assumed that the circuit 100 is located on a single integrated circuit or hybrid circuit.

In one or more embodiments, test circuit 100 may include data flow controller 106 which may receive as inputs scan shift signal 110 and AC test signal 120, data source 102, input circuit 200, target 300, output circuit 400, and data destination 104. The input circuit 200 and the output circuit 400 may be formed from a plurality of latches, preferably latches that exist on-chip, but which may be taken out of their normal function mode during testing. In one or more embodiments, target 300 may be a SRAM or other memory device. However, in one or more alternative embodiments, target 300 may be any other type of memory or any type of digital logic circuit or combination of circuits capable of generating output data as a function of input data. For example, in one or more embodiments, target 300 may include one or more combinational digital logic gates. When the target 300 is, for example, an SRAM memory, an output signal from data flow controller 106 may configure target 300 to operate in a test mode.

Data flow controller 106 may include any digital logic circuitry suitable for implementing a scan mode and/or an AC test mode for circuit 100. Data source 102 may be an SRAM, other form of memory, or any circuit capable of supplying data to input circuit 200. In one or more embodiments, the data source 102 may be disposed off-chip or on-chip. Similarly, data destination 104 may be an SRAM, other type of memory, or any circuit capable of receiving data from output circuit 400. Again, the data destination 104 may be disposed off-chip or on-chip. Data destination 104 may, but need not, be able to store test output data received from output circuit 400.

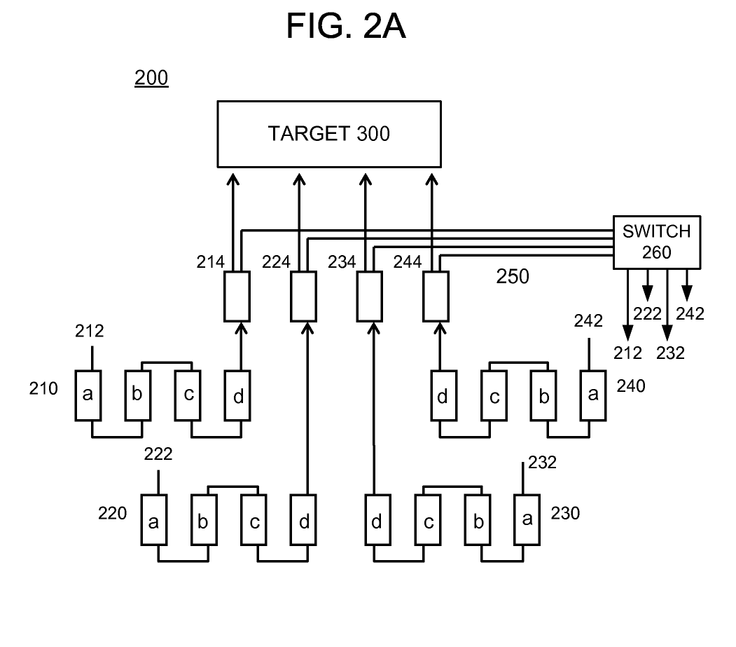

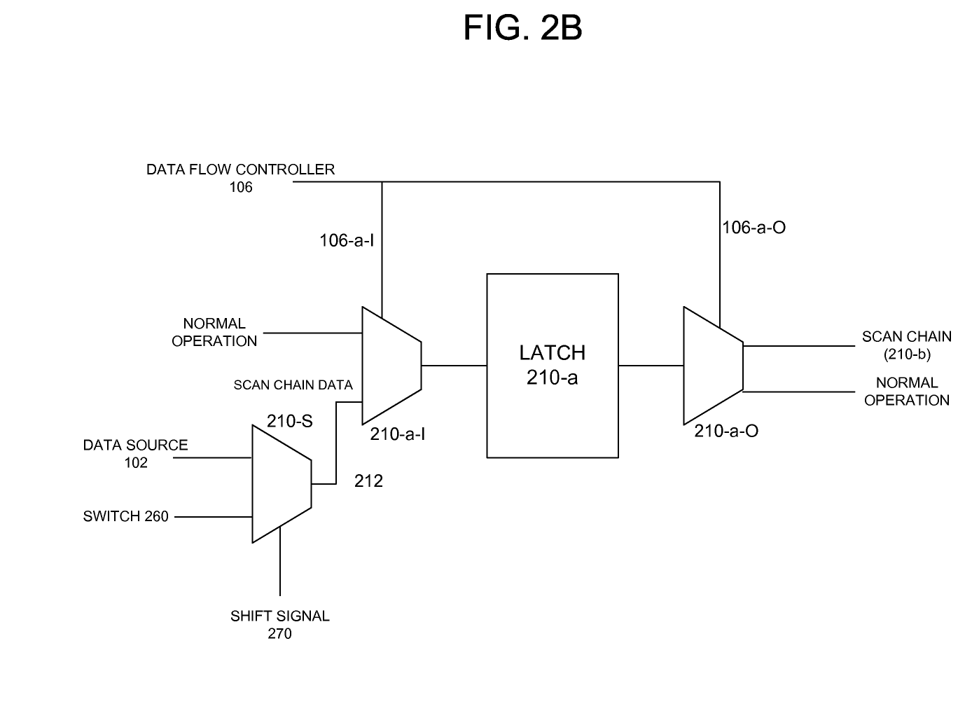

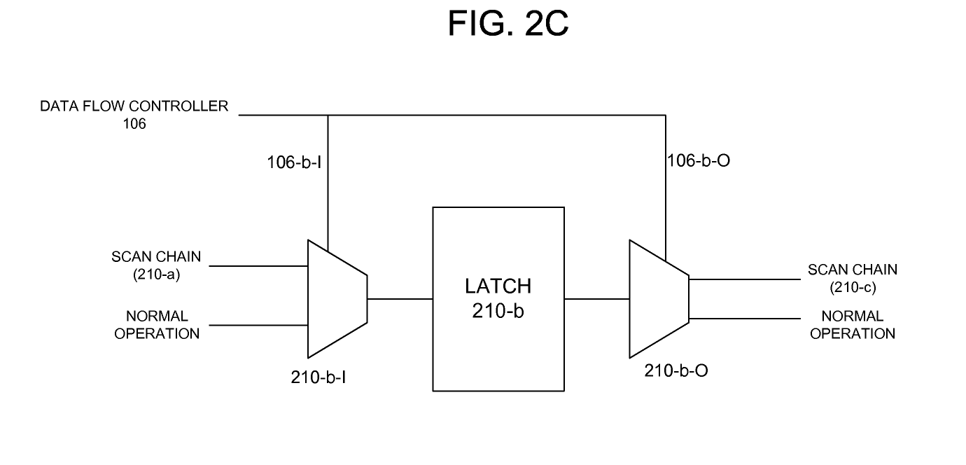

A general description of the operation of test circuit 100 is provided below, followed by a more detailed description which references FIGS. 2-4. In one or more embodiments, circuit 100 may enter a scan mode after which test input data may be loaded or scanned into input circuit 200 from data source 102. Circuit 100 may then enter an AC test mode. Plural streams of test input data may then be rapidly communicated along input circuit 200 to the target 300. Target 300 may then generate test output data and rapidly transmit this data to output circuit 400. Circuit 100 may then transition back into the scan mode, by setting scan shift signal 110 low, and the test output data may be transmitted from output circuit 400 to data destination 104. The constituent parts of FIG. 1 are discussed in greater detail in connection with FIGS. 2-4.

FIG. 2A is a block diagram showing the input circuit 200 portion of circuit 100 of FIG. 1 in greater detail, in accordance with one or more embodiments of the present invention. Herein, a set or series of data latches forming a chain may be referred to as a data-latch scan chain, or simply as a “scan chain.” A data path, whether an input data path or an output data path, may include one or more data-latch scan chains and/or other registers. However, a data path is not limited to being implemented using one or more data-latch scan chains. The latches disclosed herein may be implemented using flip-flop circuits, or may alternatively be implemented using any suitable circuit or combination of circuits. Herein, the term “latch” generally corresponds to the term “register.”

In one or more embodiments, input circuit 200 may include data latch scan chains 210, 220, 230, and 240. Data latch scan chains 210, 220, 230, and 240 may each include four latches plus respective final registers 214, 224, 234, and 244 disposed prior to target 300. Data-latch scan chains 210, 220, 230, and 240 may include respective input pins 212, 222, 232, and 242. Scan chain 210 may include latches 210-a, 210-b, 210-c, and 210-d and/or final latch/register 214. Each of scan chains 220, 230, and 240 may also each include four latches labeled a-d, and/or respective separately numbered final latches 214, 224, 234, and 244.

The configuration and interconnections among the latches of the scan chains 210, 220, 230, and 240 shown in FIG. 2A are the result of entering the test mode of operation (the scan mode and/or the AC test mode). In other words, the respective sets of input latches forming the scan chains 210, 220, 230, and 240 have been selected from among the plurality of latches of the main IC to be used in the testing process. Thus, the input latches (and output latches discussed later herein) are typically already part of the IC and, under normal operating modes, perform functions that permit the IC to operate. The testing designer, however, selects the input and output latches from among the latches of the IC to be used in the scan chain testing process. Since the AC scan chain testing process performs dynamic (AC) testing, only a subset of the existing latches of the IC may be selected as input/output latches for the scan chain test process. Indeed, if a latch is selected that is too far from the inputs/output of the target circuit 300, then the line length, the impedances of the interconnections, or other potential sources of electromagnetic interference may interfere with the AC testing process. In this regard, the step of selecting the respective sets of input latches preferably includes ensuring that at least one of: (i) interconnections between adjacent latches, and (ii) interconnections between the respective sets of latches and the respective input (or output) nodes of the target 300, are capable of transmitting the sets of input bits serially into the respective input nodes of the target circuit 300 at a high frequency without substantially distorting the input bits and timing thereof. The transmission frequency must be high enough to permit dynamic testing of the target circuit 300. Thus, for example, the selection of the respective sets of input latches forming the scan chains 210, 220, 230, 240 should include ensuring that interconnections between adjacent latches are relatively short such that transmitting the input bits serially into the respective input nodes of the target circuit 300 does not result in substantial distortion thereof.

While FIG. 2A shows a circuit that includes four scan chains, with each scan chain including five registers for delivering sets of input data to the target 300, it will be appreciated that, in alternative embodiments, fewer or more than four scan chains may be used, and that fewer or more than five registers may be deployed within each scan chain. Moreover, while all of the scan chains shown in FIG. 2A are of equal length (that is, have equal numbers of registers), in one or more alternative embodiments, scan chains leading to a target may include different numbers of registers.

Selector circuits may be employed to switch the input/output connections of the selected latches between normal operating modes and the scan chain testing mode. In one or more embodiments, the data flow control circuit 106 is operable to: reconfigure connections of at least some of a plurality of sets of input latches, selected from among a plurality of latches of the main circuit, from normal connections such that each set of input latches is connected in series and directs an input bit stream from the data source 102 (or the data source nodes thereof) into an associated input node of the target circuit 300.

In one or more embodiments, the scan chains of input circuit 200 may be formed using selector circuits among the selected latches. With reference to FIGS. 2B and 2C, one portion of the selector circuits capable of configuring the interconnections of latches 210a and 210b will now be described. Scan chains 210, 220, 230, and 240 may be established in preparation for conducting an AC test through the use of the data flow controller 106.

In one or more embodiments, the circuit of FIG. 2B may include latch 210-a, scan chain input pin 212, input latch selector 210-a-I, output latch selector 210-a-O, and scan data selector 210-S. Selectors 210-S and 210-a-I may select from among two possible sources of data, based on the value of an input signal, and transfer data from the selected source to a single output line. Selector 210-a-O may direct data from a single input line or pin to one of two possible output lines based on the value of the output of data flow controller 106. Selector 210-a-O may aid in insulating data in scan chain 210 from distortion due to electrical noise. Selector 210-a-I and selector 210-a-O may receive control signals 106-a-I and 106-a-O, respectively, from data flow controller 106. Control signals 106-a-I and 106-a-O may be suitably timed to cooperate with the progress of data flow through the circuitry shown in FIG. 2B. Selector 210-S may receive data input from data source 102 (FIG. 1) and switch 260. The data transferred through selector 210-S may be based on the value of shift signal 270. When the value of the shift signal 270 is low, selector 210-S may transfer data from data source 102 to output of selector 210-S for input to selector 210-a-I. When the value of the shift signal 270 is high, selector 210-S may transfer data from switch 260 to the output of selector 210-S. In this manner, selector 210-S may operate to acquire fresh scan chain data from data source 102 or to receive scan chain data that has been shifted from the output of another scan chain to scan chain 210 of which circuit 210-a-ckt may be a part. It is noted that the output of selector 210-S may be located on a same circuit node as scan chain input pin 212. In embodiments in which switch 260 is omitted, data source 102 may be connected directly to scan chain input pin 212.

In one or more embodiments, selector 210-a-I may select between scan chain data as provided by the output of selector 210-S and data for normal operation of circuit 100. When signal 106-a-I from data flow controller 106 is low, which may correspond to a normal operation mode of circuit 100, selector 210-a-I may transfer normal operation data therethrough to latch 210-a. When signal 106-a-I from data flow controller 106 is high, which condition may correspond to circuit 100 being in the scan mode, selector 210-a-I may transfer the scan chain data from the output of selector 210-S through selector 210-a-I to latch 210-a. The transferred data may be stored in latch 210-a, and upon receiving an appropriate clock signal, be transferred out to selector 210-a-O.

In one or more embodiments, selector 210-a-O may transfer the data from latch 210-a to the normal operation (normal mode) output thereof when the output from data flow controller 106 is low. When signal 106-a-O from data flow controller 106 is high, selector 210-a-O may transfer data from latch 210-a to scan chain 210 (FIG. 2A), and more particularly, to the next latch in scan chain 210, which may be latch 210-b. In one or more alternative embodiments, selector 210-a-O may be omitted from circuit 200. In this case, the next latch in scan chain 210 may simply ignore data that would otherwise be transmitted to the normal operation output of selector 210-a-O.

With reference to FIG. 2C, the selector circuit may include latch 210-b, input latch selector 210-b-I and output latch selector 210-b-O. Selector 210-b-I and selector 210-b-O may receive control signals 106-b-I and 106-b-O, respectively, from data flow controller 106. Control signals 106-b-I and 106-b-O may be suitably timed to cooperate with the progress of data flow through the circuitry shown in FIG. 2C. FIG. 2C is provided herein to illustrate the operation of an “intermediate latch” that is, a latch not receiving data directly from a source outside scan chain 210, such as data source 102. When signal 106-b-I from data flow controller 106 is low, normal operation data may enter and pass through selector 210-b-I, enter latch 210-b, be transmitted in turn to the input of selector 210-b-O, and in turn be directed to the normal operation output of selector 210-b-O. When signal 106-b-I from data flow controller 106 is high, scan chain data from latch 210-a may be transferred through selector 210-b-I and be stored in latch 210-b. This scan chain data may then be transmitted to the input of selector 210-b-O and may be directed to the next latch in scan chain 210, which may be latch 210-c.

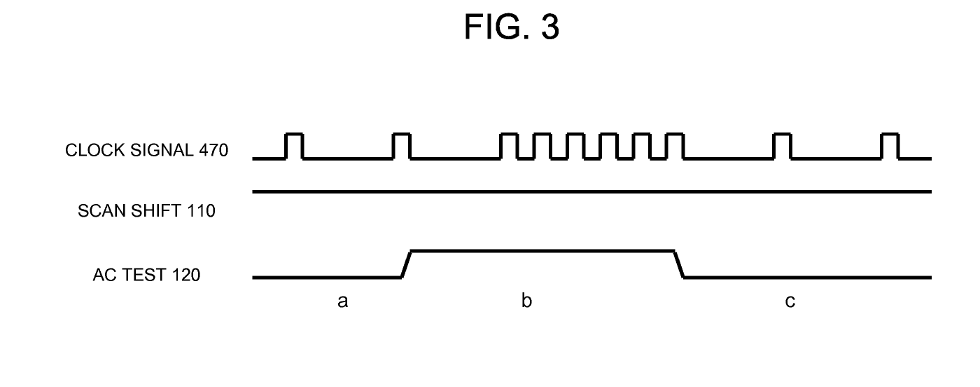

In one or more embodiments, test circuit 100 may enter the scan mode, and test input data may be written into scan chains 210, 220, 230, and 240. The test input data is preferably entered with the AC test signal 120 (see FIGS. 1 and 3) set low, and the scan shift signal 110 set high. AC test signal 120 being low may cause clock signal 470 (FIG. 3) to be set to a relatively low frequency, to enable an orderly loading of test input data into scan chains 210, 220, 230, and 240. FIG. 3 shows plots of three signals: clock signal 470, scan shift signal 110, and AC test signal 120. In the embodiment of FIG. 3, scan shift signal 110 is high throughout the illustrated time period. In one or more embodiments, in an early portion of the illustrated time period, designated by “a”, scan shift signal 110 may be high, and AC test signal 120 may be low. Moreover, when the above-described combination of signal values is active, clock signal 470 may be set to a relatively low frequency.

In one or more embodiments, having established the above-described signal levels, test input data may be scanned into scan chains 210, 220, 230, and 240 from data source 102. In the embodiment shown in FIG. 2A, each of the four scan chains may have four bits scanned in. For each scan chain, a sequence of test input data bits may be scanned in to scan chains 210, 220, 230, and 240, using respective scan chain input pins 212, 222, 232, and 242. Thereafter, each data bit may proceed along four consecutive latches of each scan chain, to the registers labeled “a”, “b”, “c”, and “d”, in each of scan chains 210, 220, 230, and 240. Preferably, the process of scanning data into the scan chains may continue until four registers in each of scan chains 210, 220, 230, and 240 have test input data therein. In other words, the plurality of sets of input bits are scanned into the respective sets of input latches of each chain 210, 220, 230, 240 such that each latch of each set of input latches contains a respective bit of an associated one of the sets of input bits.

In one or more embodiments, once the test input data has been scanned into scan chains 210, 220, 230, and 240, the AC test signal 120 may transition to a high level, and the test input data in the scan chains may be relatively rapidly transmitted to target 300. The scanning of each of the sets of input bits serially into the respective input nodes of the target circuit 300 is preferably carried out at a sufficiently high frequency to dynamically test the target circuit 300. It is noted that the data flow control is operable such that the plurality of sets of input bits are scanned into the respective sets of input latches at a first clock frequency, and each of the sets of input bits are scanned serially into the respective input nodes of the target circuit 300 at a second frequency, where the first frequency is lower than the second frequency.

In one or more embodiments, while test input data is being transmitted toward target 300, the same data may be simultaneously directed to switch 260 (FIG. 1), for ultimate retransmission back into scan chain input pins 212, 222, 232, and 242 of scan chains 210, 220, 230, and 240, respectively. Switch 260 may be configured to reassign the output from the four scan chains 210, 220, 230, and 240, as received from final registers 214, 224, 234, and 244, respectively. Switch 260 may be implemented using a combination of digital logic gates or any other circuit or combination of circuits suitable for reassigning data sequences among the scan chains.

In one or more embodiments, in order to vary the sequence of bits, which may be referred to herein as test patterns, provided as test input data to target 300, without necessarily acquiring additional data from a source external to scan chains 210-240, data may be shifted from one scan chain to another, concurrently with the transmission of test input data to the target 300. Alternatively, the test input data may be stored in switch 260 during a given AC test mode data transmission, and be shifted among the scan chains only once the given AC test mode data transmission has concluded.

In one or more embodiments, data emerging from scan chain 210 may be transferred to scan chain 220. A similar transfer may be implemented from scan chain 220 to scan chain 230, from scan chain 230 to scan chain 240, and finally, from scan chain 240 to scan chain 210. In this manner, four separate bit sequences, each having four bits, may be directed to each of four inputs to target 300 without having to scan new data into the scan chains 210, 220, 230, and 240. In one or more embodiments, shift signal 270 may be transmitted from switch 260 to the scan chains to signal the latter to receive data from switch 260 instead of data source 102, or other data source. While one data shifting scheme has been discussed, the present invention is not limited to such data shifting approach. Various other data shifting schemes may be employed, and all such variations are intended to be included within the scope of the present invention.

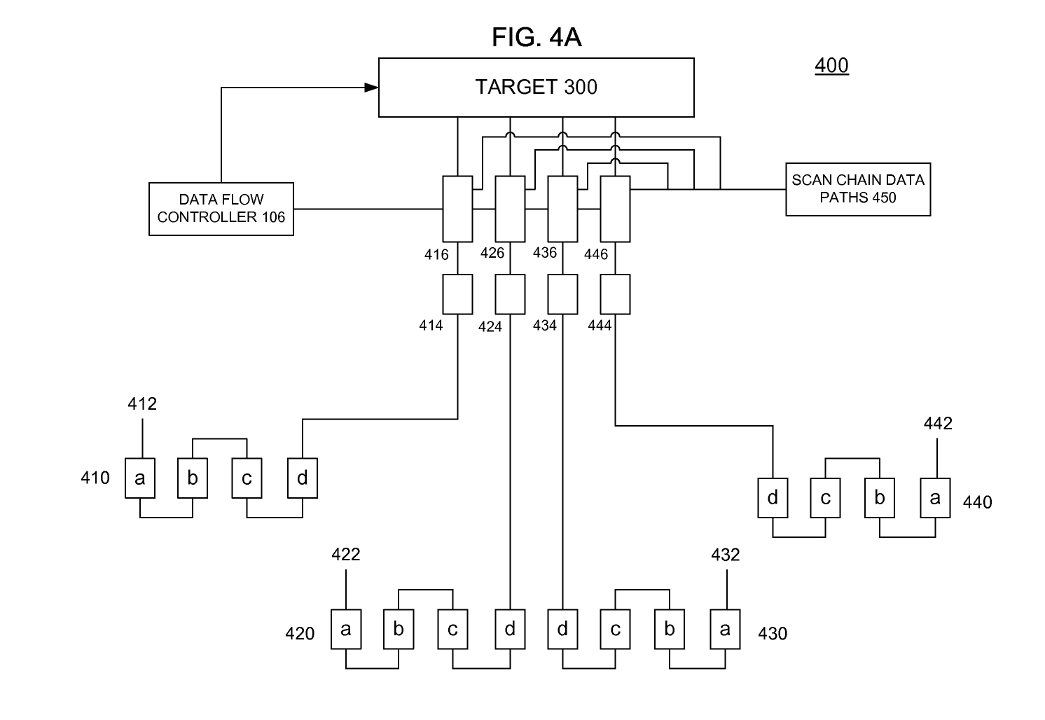

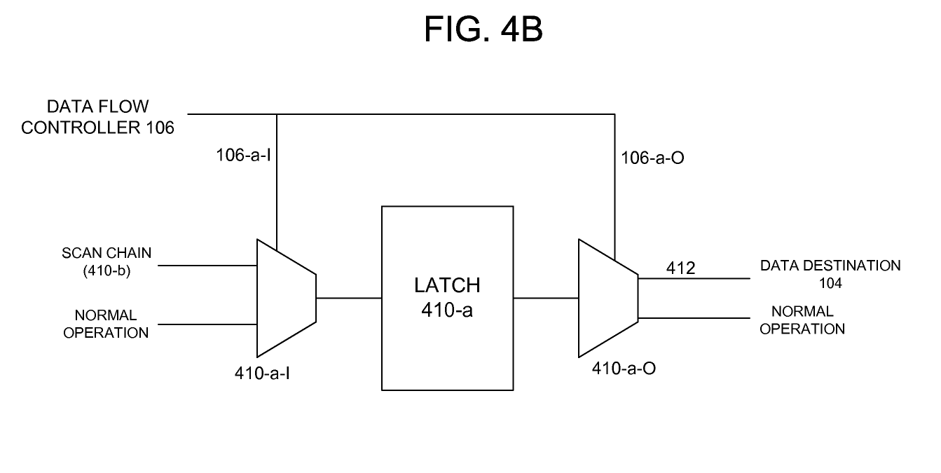

FIG. 4A is a block diagram showing output circuit 400 of circuit 100 of FIG. 1 in greater detail, in accordance with one or more embodiments of the present invention. In one or more embodiments, output circuit 400 may include data flow controller 106, selectors 416, 426, 436, and 446, output scan chains 410, 420, 430, 440, which may include respective output pins 412, 422, 432, and 442, and respective first registers 414, 424, 434, and 444, succeeding the respective selectors.

In one or more embodiments, after receiving the test input data from the input circuit 200, target 300 may generate test output data in response thereto. Thereafter, the target 300 may transmit the test output data out of target 300 to output circuit 400. In one or more embodiments, the AC test signal 120 from data flow controller 106 may be high while test input data is directed toward the target 300, while the target 300 generates test output data, and/or while the target 300 transmits the test output data out of the target to output circuit 400.

In one or more embodiments, when the AC test signal 120 is high, normal data paths may be selected at selectors 416, 426, 436, and 446 which may enable test output data to be transmitted to registers 414, 424, 434, and 444. In such embodiments, the other registers in scan chains 410, 420, 430, and 440 may have their respective selectors controlled so as to select scan chain data paths, even while registers 414, 424, 434, and 444 receive data along respective normal mode paths. In this manner, the AC test signal 120 from data flow controller 106 may operate to undo the scan chain data path selection setting for only a portion of the registers within circuit 400. Further, where target 300 includes one or more digital logic circuits, AC test signal 120 from data flow controller 106 may be directed thereto, and may operate to implement normal data paths in target 300 to ensure normal operation of the target 300 during AC testing thereof.

In one or more embodiments, test output data may be transmitted out of target 300, through selectors 416, 426, 436, and 446, then through registers 414, 424, 434, and 444, and through the remainder of scan chains 410, 420, 430, and 440. In this embodiment, the number of output scan chains, and the number of data latches storing test output data in each such scan chain, may correspond to the number of scan chains and the number of stored bits in each scan chain of the input circuit 200 of FIG. 2A. However, in one or more alternative embodiments, the number of output scan chains may differ from the number of input scan chains. Moreover, the number of registers within each output scan chain may differ from the number of registers within each input scan chain. Further, the scan chains within the input circuit 200 and those within the output circuit 400 may include different numbers of registers, and all such variations are intended to be included within the scope of the present invention.

In one or more embodiments, once scan chains 410, 420, 430, and 440 have received all the test output data, test circuit 100 may transition from the AC test mode to the scan mode. Conducting this transition may include transitioning the AC test signal 120 from high to low, while maintaining the scan shift signal 110 at a high level.

In one or more embodiments, once the scan mode is in effect, the test output data may be scanned out of input circuit 400 to data destination 104 (FIG. 1) or other device. Preferably, the test output data is scanned out of scan chains 410, 420, 430, and 440 through respective scan chain output pins 412, 422, 432, and 442. The test output data may be directed to data destination 104, another series of registers, or one or more other selected data storage devices.

In connection with the output circuit 400, the data flow control circuit 106 is preferably operable to reconfigure connections of at least some of the plurality of sets of output latches of the scan chains 410, 420, 430, 440, selected from among the plurality of latches of the main IC. The reconfiguration involves a change from normal connections within the main IC such that each set of output latches is connected in series and directs an output bit stream, responsive to an associated one of the input bit streams, from an associated output node of the target circuit 300. The sets of output bits are scanned serially from the respective output nodes of the target circuit 300 into the respective sets of output latches of the scan chains 410, 420, 430, 440 at the sufficiently high frequency such that each latch of each set of output latches contains a respective bit of an associated one of the sets of output bits.

Thereafter, the data flow control circuit 106 is further operable to scan the sets of output bits from the respective sets of output latches such that the sets of output bits may be compared with expected sets of output bits to determine whether the target circuit is operational. In this regard, the data flow control circuit 106 is operable to: (i) scan each of the sets of output bits serially from the respective output nodes of the target circuit 300 at a first frequency, and (ii) scan the plurality of sets of output bits from the respective sets of output latches of the scan chains 410, 420, 430, 440 at a second clock frequency, where the first frequency is higher than the second frequency. As the first frequency is a relatively high frequency, the interconnections between adjacent output latches are relatively short such that transmitting the output bits serially from the respective output nodes of the target circuit 300 does not result in substantial distortion thereof.

FIG. 4B is a block diagram showing latch 410-a of the output circuit of FIG. 4A in greater detail, in accordance with one or more embodiments of the present invention. Latch circuit 410-a-ckt may include latch 410-a and selectors 410-a-I and 410-a-O. Selector 410-a-I and selector 410-a-O may receive control signals 106-a-I and 106-a-O, respectively, from data flow controller 106. Control signals 106-a-I and 106-a-O may be suitably timed to cooperate with the progress of data flow through the circuitry shown in FIG. 4B. In one or more embodiments, when signal 106-a-I from data flow controller 106 is low, which may correspond to a normal operation mode of circuit 100, normal operation data may be transmitted through selector 410-a-I and enter latch 410-a. The normal operation data may then be transmitted to the input of selector 410-a-O and toward the normal operation output thereof. In one or more embodiments, when signal 106-a-I from data flow controller 106 is high, which may correspond to circuit 100 being in the scan mode, scan chain data from latch 410-b may enter selector 410-a-I and may be selected for transmission therethrough, and enter latch 410-a. The scan chain data may proceed to the input of selector 410-a-O. Selector 410-a-O may then direct the scan chain data to data destination 104, via scan chain output pin 412. In this manner, test output data that proceeds along scan chain 410 may be transferred out of latch 410-a (the final latch in scan chain 410).

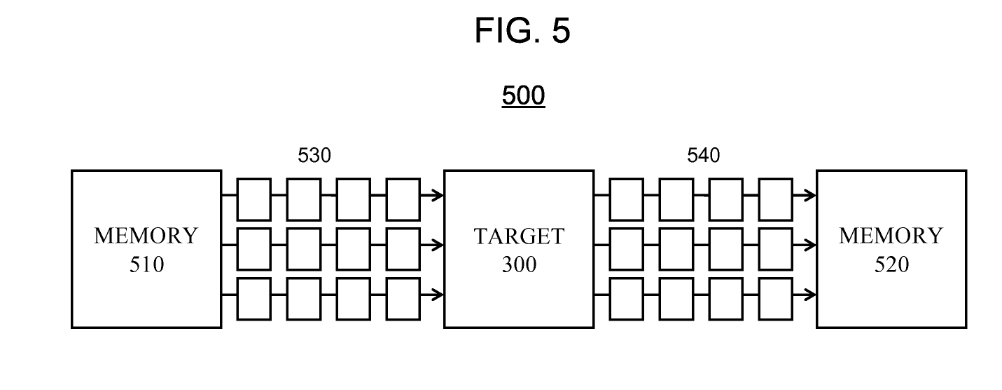

FIG. 5 is a block diagram of a circuit 500 for AC testing a target 300 in accordance with one or more alternative embodiments of the present invention. Circuit 500 may include memory 510, target 300, memory 520, data path 530, and data path 540. In one or more embodiments, memory 510, target 300, and memory 520 may be SRAMs, or other types of memory devices. Target 300 may also be any type of digital logic device capable of generating an output based on test input data. In one or more embodiments, data paths 530 and 540 may each include three scan chains that may each include four registers. However, in one or more alternative embodiments, fewer or more than four registers may be included in one or more of the scan chains of circuit 500. Moreover, fewer or more than three scan chains may be included in data path 530 and/or data path 540.

In one or more embodiments, circuit 500 may operate substantially the same way as circuit 100 of FIG. 1, with memory 510 serving as data source 102 and memory 520 serving as data destination 104. The discussion of the operation of circuit 100 is therefore applicable to one or more embodiments of circuit 500. Accordingly, the details of that discussion are not repeated in this section.

The memory 510 is operable to store a plurality of sets of input bits. For example, the memory 510 may store a plurality of different sets of input bits for at least one of the input nodes of the target circuit 300. This provides a high degree of flexibility in providing different test patters to the target 300. The data flow control circuit 106 (not shown) is operable to: (i) scan the sets of input bits from the memory 510 into the respective sets of input latches 530 such that each latch of each set of input latches contains a respective bit of an associated one of the sets of input bits; and (ii) scan each of the sets of input bits serially into the respective input nodes of the target circuit 300 at a sufficiently high frequency to dynamically test the target circuit. The data flow control circuit 106 (not shown) is further operable to: scan each of the sets of output bits serially from the respective output nodes of the target circuit 300 into the respective sets of output latches 540 at the sufficiently high frequency such that each latch of each set of output latches contains a respective bit of an associated one of the sets of output bits; and (ii) scan the sets of output bits from the respective sets of output latches into the memory 520.

In one or more alternative embodiments, testing target 300 of circuit 500 may be simplified with respect to the target testing discussed in connection FIGS. 1-4. Specifically, in the embodiment of FIG. 5, data paths 530 and 540 may be disposed between memory 510 and target 300 (data path 530) and between target 300 and memory 520, respectively, in the normal function mode of circuit 500. Such an alternative arrangement may beneficially remove the need for configuring particular “test mode” scan-chain data paths, as discussed earlier in this document, since data paths 530 and 540 may provide the needed paths in the normal function mode of circuit 500.

In such alternative embodiments, the ability to use normal function mode data paths for conducting AC testing of target 300 may depend on the run length and impedance of the data paths and the routing of the registers within the data paths 530, 540. If the characteristics of run length, routing, and impedance of the data paths 530 and 540 are such as to not distort the results of the AC testing of target 300, then the normal function data paths may be beneficially employed to transmit data to and from target 300 during the AC testing thereof. The following discussion applies to embodiments of circuit 500 in which the above-listed characteristics do not inhibit effectively AC testing the target 300.

In embodiments discussed earlier in this document, two different operational modes may be entered as part of the process of AC testing target 300: the scan mode and the AC test mode. The scan mode may be employed to load data into scan chains coupled to the target 300, and the AC test mode may be employed to relatively rapidly transmit the test input data to the target. In or more embodiments of circuit 500, transitions between the scan mode and the AC test mode may be avoided, thereby simplifying the operation thereof.

In one or more embodiments, test input data may be stored in memory 510, and the AC test mode may be entered. When testing of target 300 is set to start, memory 510 may transmit the test input data along data path 530, in the AC test mode, to target 300. Target 300 may then generate test output data from the test input data and transmit same along data path 540 to memory 520. Memory 520 may then store the test output data. Additionally or alternatively, memory 520 may retransmit the test output data to another memory, or other digital device.

In other embodiments discussed herein, the steps of loading test input data into input circuit 200, transmitting the test input data to target 300, generating the test output data by target 300, and transmitting the test output data out of target 300 to the output circuit 400 may be discrete steps, which are conducted in succession. In these other embodiments, one or more the above-listed steps may be concluded prior to beginning a subsequent step. For example, in one or more embodiments, the test input data may be completely loaded into input circuit 200, prior to sending any of this data to the target 300 (FIG. 1).

One or more alternative embodiments of circuit 500 may provide the option of conducting one or more of the above-listed steps concurrently. Thus, in one or more embodiments, memory 510 may continue to transmit test input data along data path 530 to target 300, while target 300 concurrently generates test output data and transmits the test output data along data path 540 to memory 520. Such operation may be enabled by layout of circuit 500 in which data paths 530 and 540 form connections between their respective data sources and destinations in the normal function mode (normal operation mode) of circuit 500. If needed, an additional memory, such as a SRAM, may be connected to target 300 to provide address and control data thereto to aid target 300 to concurrently read test input data and write test output data.

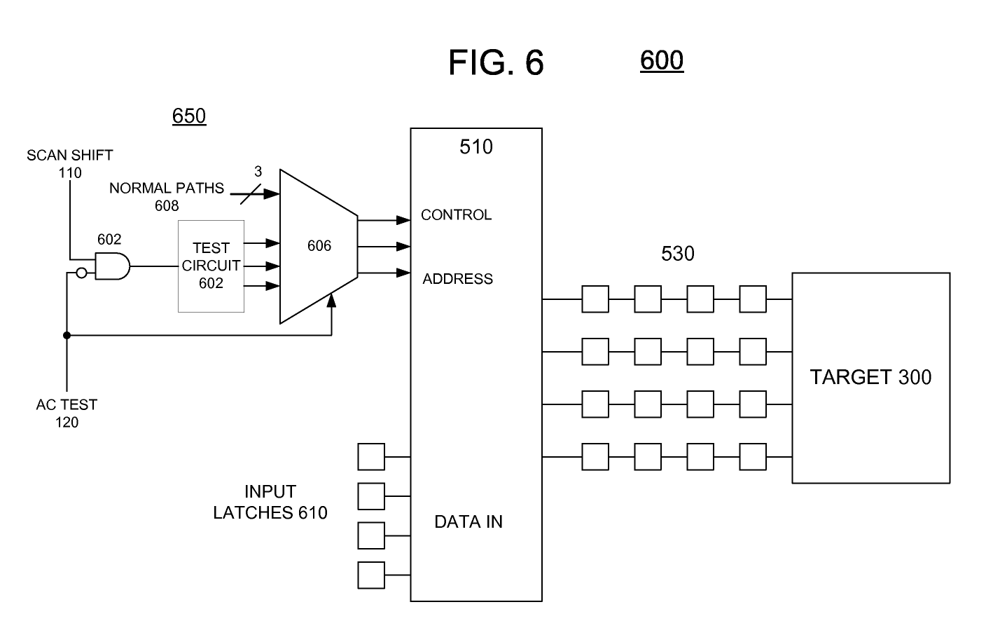

FIG. 6 is a block diagram of a circuit 600 for AC testing a target 300 in accordance with one or more embodiments of the present invention. Circuit 600 may include memory 510, data path 530, and target 300 of circuit 500, and data loading circuit 650. Data loading circuit 650 may include AND gate 602 which may receive scan shift signal 110 and AC test signal 120 as inputs, test circuit 602, selector 606, normal paths 608, and input latches 610. Test circuit 602 may be operable to transmit control and address information to memory 510 for the loading of test input data thereto from input latches 610. Memory 510, data path 530 and target 300 may operate in the same manner described in connection with circuit 500 of FIG. 5 along with the components of FIG. 5 not shown in FIG. 6. However, in order to more fully illustrate the features of data loading circuit 650, data path 540 and memory 520 of circuit 500 are not shown in FIG. 6.

In one or more embodiments, although data path 530 may include scan chains that may transmit data at high frequencies, the loading of data into memory 510 in preparation for AC testing target 300 need not be conducted at a rapid rate. Accordingly, data loading circuit 650 may be operable to load data into memory 510 from input latches 610 while in a scan shift mode. Thereafter, the test input data which has been loaded into memory 510, may be rapidly transmitted along data path 530 for AC testing of target 300.

In one or more embodiments, when scan shift signal 110 is high, and AC test signal 120 is low, selector 606 may be set to transmit data from test circuit 602 to memory 510. Once selector 606 is set in the described manner, test circuit 602 may transmit control and address information to suitable ports in memory 510 to control the reading of test input data from input latches 610. The control information may include a “read” command. The address information may follow a simple algorithm such as incrementing a previously used address value. The process of loading memory 510 may continue until all test input data needed for an AC test of target 300 is stored within memory 510. Thereafter, the AC testing of target 300 may proceed as described in connection with circuit 500 of FIG. 5. When the scan shift mode is no longer in effect, data from normal paths 608 may be transmitted through selector 606 to memory 510.

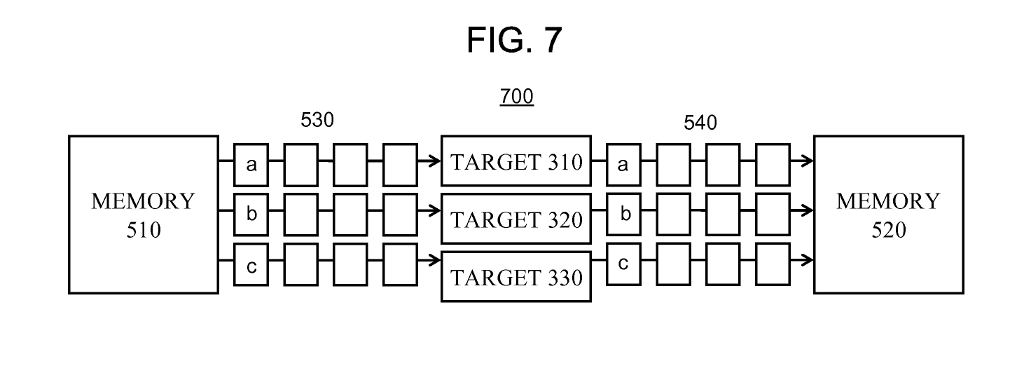

FIG. 7 is a block diagram of a circuit 700 for AC testing a plurality of targets 310-330 in accordance with one or more alternative embodiments of the present invention. In a sense, the target circuit 300 may be considered to include respective sub-target circuits 310, 320, 330, where each of the input nodes is coupled to a respective one of the sub-target circuits. Circuit 700 may include memory 510, data path 530, targets 310, 320, and 330, data path 540, and memory 520.

Memories 510 and 520 and targets 310, 320, and 330 may be SRAMs or other form of memory device. Targets 310, 320, and 330 may also be any other type of digital device capable of generating test output data based on test input data. Data paths 530 and 540 may each include a plurality of scan chains. Data path 530 may include scan chains 530-a, 530-b, and 530-c, which are indicated with “a”, “b”, and “c”, respectively, in FIG. 7. Likewise, data path 540 may include scan chains 540-a, 540-b, and 540-c. While the data paths 530, 540 of circuit 7 each include three scan chains, fewer or more than three scan chains may be included in data path 530 and/or data path 540.

The embodiment of FIG. 7 may be employed where a number of bits from a parallel output port of memory 510 exceeds the number of bits available at an input port of target 310. In this situation, a single memory 510 may be used to supply test input data to a plurality of targets. While three targets 310, 320, and 330 are shown in circuit 700, it will be appreciated by those of skill in the art that fewer or more than three targets could be supplied with data from memory 510, and all such variations are intended to be included within the scope of the present invention.

In one or more embodiments, circuit 700 may have a structure and function that is substantially the same as that of circuit 500, except that the separate streams of test input data may be directed to a plurality of respective targets instead of being directed to a plurality of respective input pins of a single target. Moreover, the data transfer operations, in the scan mode and AC test mode, may occur in much the same way in circuit 700 as in circuit 500. Accordingly, the details of such operation are not repeated in this section.

As with circuit 500, the data paths 530, 540 of circuit 700 may be configured in two separate ways. In one or more embodiments, the scan chains of data paths 530 and 540 may be established by activating scan shift signal 110 to link the registers forming the respective scan chains together for the purpose of scanning in test input data in preparation for AC testing. And, as with circuit 500, in one or more alternative embodiments, the scan chains of data paths 530, 540 may form normal function mode links or paths between their respective start and end points, thereby removing a need for configuring a special purpose connection for testing purposes, using scan shift signal 110. Since the operation of both of the above configurations was discussed in connection with different embodiments of circuit 500, for the sake of brevity, that discussion is not repeated in this section.

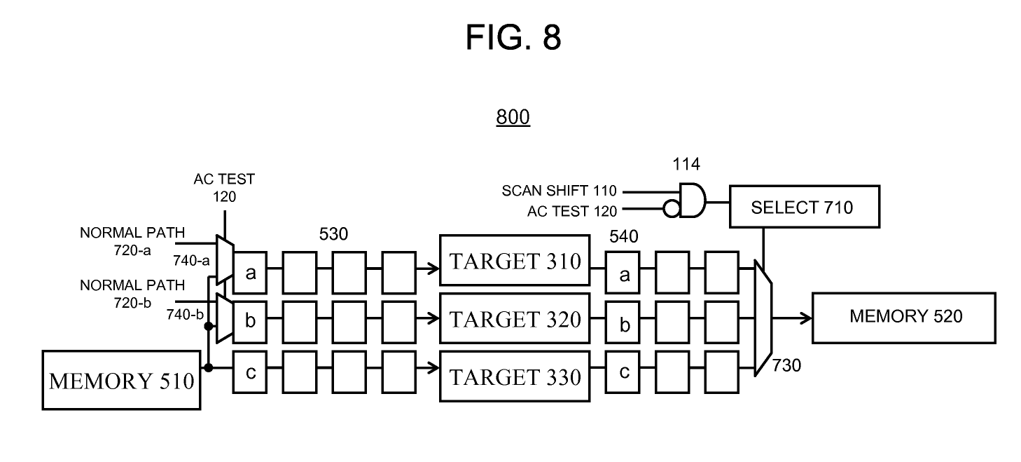

FIG. 8 is a block diagram of a circuit 800 for AC testing targets 310, 320, and 330 in accordance with one or more alternative embodiments of the present invention. Circuit 800 may include memory 510, selectors 740-a and 740-b, receiving normal data paths 720-a and 720-b, respectively, as inputs and AC test signal 120 as a control signal, data path 530, targets 310, 320, and 330, data path 540, AND gate 114 which may receive scan shift signal 110 and AC test signal 120 as inputs, select register 710, selector 730, and memory 520.

Before discussing the operation of circuit 800 in detail, an overview of the similarities and differences between circuit 800 of FIG. 8 and circuit 700 of FIG. 7 is presented here. In both circuits 700 and 800, test output data emerges from memory 510 may be transmitted along three scan chains to three respective targets, which may transmit test output data along three respective scan chains for storage in memory 520.

In one or more embodiments, circuit 800 may differ from circuit 700 in that, in circuit 800, memory 510 may use only a single output and thus provide the same test patterns to all three targets 310, 320, and 330. Moreover, memory 520 may employ only a single input. Thus, a select register 710 may be employed to coordinate the transfer of test output data from the three scan chains of data path 540 to the single input to memory 520.

In one or more embodiments, as with test circuits previously discussed herein, test input data may be scanned into scan chains 530-a, 530-b, and 530-c from memory 510, during which operation, the scan mode may be active. Selectors 740-a and 740-b may select memory 510 as a data source to scan test input data into scan chains 530-a and 530-b, respectively. In the case of scan chain 530-c, a selector may be omitted, and the test input data may be transmitted directly from memory 510 into scan chain 530-c. In one or more embodiments, AC test signal 120 may be low while scanning the test input data into scan chains 530-a, 530-b, and 530-c of data path 530.

In one or more embodiments, once the test input data has been scanned into scan chains 530-a, 530-b, and 530-c, circuit 800 may transition to the AC test mode. This transition may cause selectors 740-a and 740-b to stop acquiring data from memory 510. In one or more embodiments, once in the AC test mode, test input data may be transmitted from scan chains 530-a, 530-b, and 530-c to targets 310, 320, and 330 respectively. Targets 310, 320, and 330 may then generate test output data based on the received test input data, and transmit the test output data to scan chains 540-a, 540-b, and 540-c, respectively.

In one or more embodiments, selector 730, select register 710, and memory 520 may cooperate to transmit the test output data from data path 540 to memory 520. In the AC test mode, the output from AND gate 114 to select register 710 may be zero and may cause select register 710 to engage in a selection regime which may cause selector 730 to transfer the output data from data path 540 to memory 520. This selection regime may include having selector 730 transfer defined quantities of data from a selected one of the scan chains in data path 540 and to then alternate between scan chains 540-a, 540-b, and 540-c as sources for data to transmit through selector 730 to memory 520. The scan chain selection and data transmission may be coordinated between select register 710 and memory 520 so that the test output data received at and/or stored in memory 520 is properly associated with the scan chain 540-a, 540-b, or 540-c that the data came from and the order in which each quantity, or packet of, test output data was received.

In one or more embodiments, select register 710 need not select from among the scan chains in any particular order, so long as data is cleared from each of the scan chains to make room as needed for further test output data from one or more of targets 310, 320, and 330.

Returning to the case discussed above in which test output data resides in scan chains 540-a, 540-b, and 540-c, select register 710 may signal selector 730 to select scan chain 540-a and transfer the data therein to memory 520. Select register 710 may then cause selector 730 to select scan chain 540-b and similarly transfer its data to memory 520. Then, this step may be repeated for scan chain 540-c. The above-recited order of scan chain selection is merely exemplary, and those of skill in the art will recognize that any order of scan chain selection may be practiced employing circuit 800.

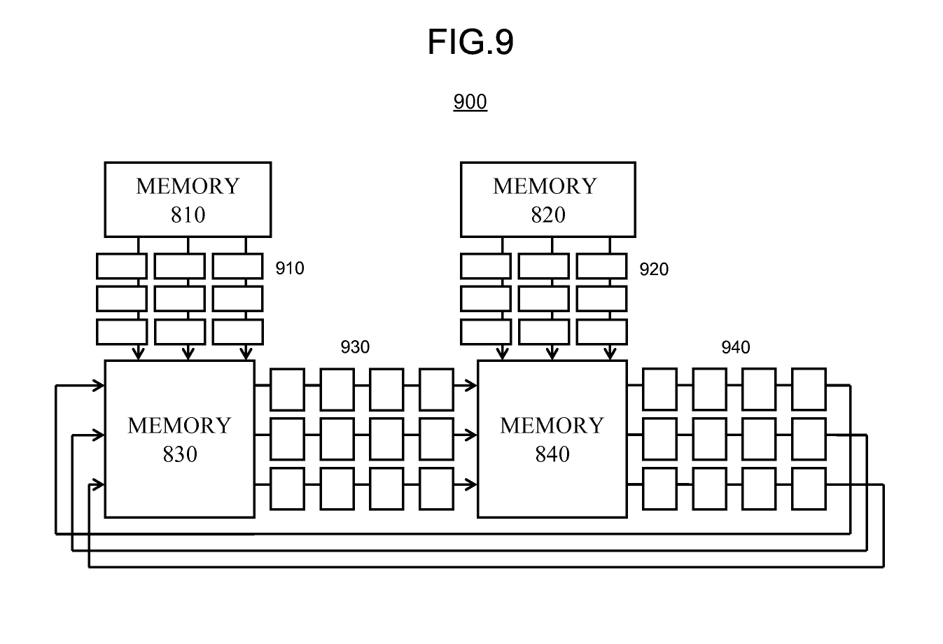

FIG. 9 is a block diagram of a circuit 900 for AC testing one or more targets in accordance with one or more alternative embodiments of the present invention. Circuit 900 may include memories 810, 820, 830, and 840; and data paths 910, 920, 930, 940. Memories 810, 820, 830, and 840 may be SRAMs. However, other types of memory and other digital devices capable of temporarily or permanently storing data may be employed. Memories 810 and 820 may serve as sources of address and control data for memories 830 and 840, respectively. Memories 830 and 840 may be used as targets for AC testing. In one or more alternative embodiments, memories 830 and 840 may be replaced or supplemented by any digital device capable of generating test output data based on test input data provided thereto. In one or more embodiments, data paths 910, 920, 930, and 940 may include one or more scan chains as have been described elsewhere in this disclosure.

In one or more embodiments, circuit 900 may enable memories 830, 840 to test one another. Each memory may receive test input data, generate test output data in response to the received test input data, store the test output data, and separately transmit other data to the other memory to serve as test input data therein.

In one or more alternative embodiments, the test output data generated by one memory may be used as test input data for the other. In this case, the effects of plural consecutive target responses to an initial set of test input data may be evaluated against templates to test the operation of more than one target, and further, to test the plural targets after more than one round of data processing activity by each of the targets.

In one or more embodiments, memory 830 may transmit test input data along data path 930 to memory 840. The test input data transmitted by memory 830 may be obtained from a store of test input data within memory 830, or may be test output data generated in response to test input data received at memory 830. In one or more embodiments, memory 820 may send address and control data to memory 840 along data path 920. The data transmissions to memory 840 from memories 830 and 820 may occur either concurrently or consecutively.

In one or more embodiments, the address and control data from memory 820 may enable memory 840 to concurrently receive test input data along data path 930 and to transmit test output data along data path 940. The receipt of test input data and the transmission of test output data by memory 840 may be conducted either consecutively or concurrently. The specific mechanisms for enabling memory 840 to receive test input data and transmit test output data either consecutively or concurrently using address and control data from memory 820 is known those of ordinary skill in the art and is therefore not described in detail herein. In one or more embodiments, memory 840 may generate test output data in response to the test input data received from memory 830. The generated test output data may be stored in memory 830.

In one or more embodiments, memory 840 may obtain test input data for AC testing memory 830 and transmit same along data path 940 to memory 830. Memory 830 may generate test output data based on the test input data received along data path 940. Returning to memory 840, the test input data slated for transmission to memory 830, may be obtained from a store of test input data within memory 840. Alternatively, the test output data slated for transmission to memory 830 may be test output data generated by memory 840 in response to test input data received at memory 840.

In one or more embodiments, memory 810 may send address and control data to memory 830 along data path 910. The data transmissions to memory 830 from memories 810 and 840 may occur either concurrently or consecutively.

In one or more embodiments, the address and control data from memory 810 may enable memory 830 to concurrently receive test input data along data path 940 and to transmit test output data along data path 930.

In the manner described above, memories 830 and 840 may both serve to a) store and transmit test input data for testing the other memory; and/or b) as an AC test target using test input data from the other memory.

In one or more embodiments, where test output data of each of memories 830 and 840 is used as input data for the other memory, the cyclical nature of the testing may serve to subject both memories 830 and 840 to testing that is more extensive and rigorous than testing either memory alone. Moreover, causing test data to be acted upon by memories 830 and 840 over a plurality of testing cycles may operate to more fully exercise memories (targets) 830 and 840 than generating one set of test output data from either memory.

In one or more embodiments, when the testing has concluded, the test output data of one or both of memory 830 and memory 840 may be compared to a template for evaluation purposes.

It is noted that the methods and apparatus described thus far and/or described later in this document may be achieved utilizing any of the known technologies, such as standard digital circuitry, analog circuitry, any of the known processors that are operable to execute software and/or firmware programs, programmable digital devices or systems, programmable array logic devices, or any combination of the above. One or more embodiments of the invention may also be embodied in a software program for storage in a suitable storage medium and execution by a processing unit.

Although the invention herein has been described with reference to particular embodiments, it is to be understood that these embodiments are merely illustrative of the principles and applications of the present invention. It is therefore to be understood that numerous modifications may be made to the illustrative embodiments and that other arrangements may be devised without departing from the spirit and scope of the present invention as defined by the appended claims.

1. A method of dynamically (AC) testing a target circuit within a main circuit, comprising:
providing respective sets of input latches from among a plurality of latches of the main circuit;
reconfiguring connections of at least some of the input latches from normal connections within the main circuit such that each set of input latches is connected in series and directs an input bit stream from an associated source node into an associated input node of the target circuit;
scanning a plurality of sets of input bits into the respective sets of input latches such that each latch of each set of input latches contains a respective bit of an associated one of the sets of input bits; and
scanning each of the sets of input bits serially into the respective input nodes of the target circuit at a sufficiently high frequency to dynamically test the target circuit.

2. The method of claim 1, further comprising selecting the respective sets of input latches from among the plurality of latches of the main circuit.

3. The method of claim 2, wherein the step of selecting the respective sets of input latches includes ensuring that at least one of: (i) interconnections between adjacent input latches, and (ii) interconnections between the respective sets of input latches and the respective input nodes, are capable of transmitting the sets of input bits serially into the respective input nodes of the target circuit at the sufficiently high frequency without substantially distorting the input bits and timing thereof.

4. The method of claim 2, wherein the step of selecting the respective sets of input latches includes ensuring that interconnections between adjacent input latches are relatively short such that transmitting the input bits serially into the respective input nodes of the target circuit does not result in substantial distortion thereof.

5. The method of claim 1, further comprising:
providing respective sets of output latches from among the plurality of latches of the main circuit;
reconfiguring connections of at least some of the output latches from normal connections within the main circuit such that each set of output latches directs a set of output bits, responsive to an associated one of the sets of input bits, from an associated output node of the target circuit;
scanning each of the sets of output bits serially from the respective output nodes of the target circuit into the respective sets of output latches at the sufficiently high frequency such that each latch of each set of output latches contains a respective bit of an associated one of the sets of output bits;
scanning the sets of output bits from the respective sets of output latches; and
comparing the sets of output bits with expected sets of output bits to determine whether the target circuit is operational.

6. The method of claim 5, further comprising selecting the respective sets of output latches from among the plurality of latches of the main circuit.

7. The method of claim 6, wherein the step of selecting the respective sets of output latches includes ensuring that at least one of: (i) interconnections between adjacent output latches, and (ii) interconnections between the respective sets of output latches and the respective output nodes, are capable of transmitting the sets of output bits serially out of the respective output nodes of the target circuit at the sufficiently high frequency without substantially distorting the output bits and timing thereof.

8. The method of claim 6, wherein the step of selecting the respective sets of output latches includes ensuring that interconnections between adjacent output latches are relatively short such that transmitting the output bits serially from the respective output nodes of the target circuit does not result in substantial distortion thereof.

9. The method of claim 1, further comprising:
feeding back and re-scanning the plurality of sets of input bits back into the respective sets of input latches; and
re-scanning each of the sets of input bits serially into the respective input nodes of the target circuit at the sufficiently high frequency to repeat the dynamic test of the target circuit.

10. The method of claim 9, wherein the step of feeding back and re-scanning the plurality of sets of input bits back into the respective sets of input latches is conducted at the sufficiently high frequency.

11. The method of claim 1, wherein:
the step of scanning the plurality of sets of input bits into the respective sets of input latches is performed at a first clock frequency;
the step of scanning each of the sets of input bits serially into the respective input nodes of the target circuit is conducted at a second frequency; and
the first frequency is lower than the second frequency.

12. The method of claim 1, wherein the target circuit includes combinational digital logic gates.

13. The method of claim 1, wherein the target circuit includes a digital memory array.

14. An apparatus for dynamically (AC) testing a target circuit within a main circuit, comprising a data flow control circuit operable to:
reconfigure connections of at least some of a plurality of sets of input latches, selected from among a plurality of latches of the main circuit, from normal connections within the main circuit such that each set of input latches is connected in series and directs an input bit stream from an associated source node into an associated input node of the target circuit;
scan a plurality of sets of input bits to the source node and into the respective sets of input latches such that each latch of each set of input latches contains a respective bit of an associated one of the sets of input bits, and
scan each of the sets of input bits serially into the respective input nodes of the target circuit at a sufficiently high frequency to dynamically test the target circuit.

15. The apparatus of claim 14, wherein the interconnections between adjacent input latches, and the interconnections between the respective sets of input latches and the respective input nodes, are capable of transmitting the sets of input bits serially into the respective input nodes of the target circuit at the sufficiently high frequency without substantially distorting the input bits and timing thereof.

16. The apparatus of claim 14, wherein:
the data flow control circuit is further operable to: (i) scan the plurality of sets of input bits into the respective sets of input latches at a first clock frequency, and (ii) scan each of the sets of input bits serially into the respective input nodes of the target circuit at a second frequency; and
the first frequency is lower than the second frequency.

17. The apparatus of claim 14, further comprising a feedback circuit operable to re-direct the plurality of sets of input bits back to the source node such that the data flow control circuit is further operable to re-scan each of the sets of input bits serially through the respective sets of input latches and into the respective input nodes of the target circuit at the sufficiently high frequency to repeat the dynamic test of the target circuit.

18. The apparatus of claim 17, wherein the feedback circuit and the data flow control circuit are operable to feedback and re-scan the plurality of sets of input bits back into the respective sets of input latches at the sufficiently high frequency.

19. The apparatus of claim 14, wherein the data flow control circuit is further operable to:
reconfigure connections of at least some of the plurality of sets of output latches, selected from among the plurality of latches of the main circuit, from normal connections within the main circuit such that each set of output latches is connected in series and directs an output bit stream, responsive the an associated one of the input bit streams, from an associated output node of the target circuit; and
scan each of the sets of output bits serially from the respective output nodes of the target circuit into the respective sets of output latches at the sufficiently high frequency such that each latch of each set of output latches contains a respective bit of an associated one of the sets of output bits.

20. The apparatus of claim 19, wherein the data flow control circuit is further operable to scan the sets of output bits from the respective sets of output latches such that the sets of output bits may be compared with expected sets of output bits to determine whether the target circuit is operational.

21. The apparatus of claim 20, wherein:
the data flow control circuit is further operable to: (i) scan each of the sets of output bits serially from the respective output nodes of the target circuit at a first frequency, and (ii) scan the plurality of sets of output bits from the respective sets of output latches at a second clock frequency; and
the first frequency is higher than the second frequency.

22. The apparatus of claim 19, wherein interconnections between adjacent output latches are relatively short such that transmitting the output bits serially from the respective output nodes of the target circuit does not result in substantial distortion thereof.

23. A method of dynamically (AC) testing a target circuit within a main circuit, comprising:
providing respective sets of input latches from among a plurality of latches of the main circuit;
reconfiguring connections of at least some of the input latches from normal connections within the main circuit such that each set of input latches is connected in series and directs an input bit stream from an associated source node into an associated input node of the target circuit;
scanning a plurality of sets of input bits from a first memory into the respective sets of input latches such that each latch of each set of input latches contains a respective bit of an associated one of the sets of input bits; and
scanning each of the sets of input bits serially into the respective input nodes of the target circuit at a sufficiently high frequency to dynamically test the target circuit.

24. The method of claim 23, further comprising:
storing a plurality of different sets of input bits for at least one of the input nodes of the target circuit in the first memory;
scanning the different sets of input bits from the first memory into an associated one of the sets of input latches; and
scanning the different sets of input bits serially into the at least one input node of the target circuit at a sufficiently high frequency to dynamically test the target circuit using the different sets of input bits.

25. The method of claim 23, further comprising:
providing respective sets of output latches from among the plurality of latches of the main circuit;
reconfiguring connections of at least some of the output latches from normal connections within the main circuit such that each set of output latches directs a set of output bits, responsive to an associated one of the sets of input bits, from an associated output node of the target circuit;
scanning each of the sets of output bits serially from the respective output nodes of the target circuit into the respective sets of output latches at the sufficiently high frequency such that each latch of each set of output latches contains a respective bit of an associated one of the sets of output bits;
scanning the sets of output bits from the respective sets of output latches into a second memory; and
comparing the sets of output bits with expected sets of output bits to determine whether the target circuit is operational.

26. The method of claim 23, further comprising:
scanning respective sets of output bits, each responsive to an associated one of the sets of input bits, from the output nodes into a second memory; and
comparing the sets of output bits with expected sets of output bits to determine whether the target circuit is operational.

27. An apparatus for dynamically (AC) testing a target circuit within a main circuit, comprising:
a first memory operable to store a plurality of sets of input bits; and
a data flow control circuit operable to: (i) reconfigure connections of at least some of a plurality of sets of input latches, selected from among a plurality of latches of the main circuit, from normal connections within the main circuit such that each set of input latches is connected in series and directs an input bit stream from an associated source node into an associated input node of the target circuit; and (ii) scan the sets of input bits from the first memory into the respective sets of input latches such that each latch of each set of input latches contains a respective bit of an associated one of the sets of input bits; and (iii) scan each of the sets of input bits serially into the respective input nodes of the target circuit at a sufficiently high frequency to dynamically test the target circuit.

28. The apparatus of claim 27, wherein:
the first memory is operable to store a plurality of different sets of input bits for at least one of the input nodes of the target circuit; and
the data flow control circuit is operable to: (i) scan the different sets of input bits from the first memory into an associated one of the sets of input latches; and (ii) scan the different sets of input bits serially into the at least one input node of the target circuit at a sufficiently high frequency to dynamically test the target circuit using the different sets of input bits.

29. The apparatus of claim 27, wherein:
the target circuit includes respective sub-target circuits; and
each of the input nodes is coupled to a respective one of the sub-target circuits.

30. The apparatus of claim 29, wherein the data flow control circuit comprises a demultiplexer circuit operable to receive the sets of input data from the first memory and channel them to the respective source nodes.

31. The apparatus of claim 27, wherein:
the apparatus further comprises a second memory; and
the data flow control circuit is further operable to:
reconfigure connections of at least some of the plurality of sets of output latches, selected from among the plurality of latches of the main circuit, from normal connections within the main circuit such that each set of output latches is connected in series and directs an output bit stream, responsive the an associated one of the input bit streams, from an associated output node of the target circuit;
scan each of the sets of output bits serially from the respective output nodes of the target circuit into the respective sets of output latches at the sufficiently high frequency such that each latch of each set of output latches contains a respective bit of an associated one of the sets of output bits; and
scan the sets of output bits from the respective sets of output latches into the second memory.

32. The apparatus of claim 31, wherein:
the target circuit includes respective sub-target circuits;
each of the output nodes is coupled to a respective one of the sub-target circuits; and
the data flow control circuit is further operable to scan the sets of output bits from the respective sets of output latches of each sub-target circuit into the second memory.

33. The apparatus of claim 27, further comprising:
a second memory; and
a multiplexer circuit operable to scan respective sets of output bits, each responsive to an associated one of the sets of input bits, from the output nodes into the second memory.

34. The apparatus of claim 27, wherein:
the target circuit includes respective sub-target circuits;
each of the output nodes is coupled to a respective one of the sub-target circuits; and
the multiplexer circuit operable to scan the respective sets of output bits from the output nodes of the respective sub-target circuits into the second memory.

35. A method of dynamically (AC) testing target circuits, comprising:
generating test output data within at least two target circuits in response to test input data;
using the test output data from a first of said target circuits as test input data to a second of said target circuits; and
using the test output data of a second of said target circuits as test input data to the first target circuit.

36. The method of claim 35, wherein the first and second target circuits are respective data memories.

37. The method of claim 36, wherein the two memories are operable to transmit receive the test input data and transmit the test output data concurrently.

38. An apparatus for dynamically (AC) testing target circuits, comprising:
a data flow controller operable to place the apparatus in an AC test mode;
at least two target circuits operable to generate test output data in response to test input data;
a first target data path operable to: (i) receive test output data of a first of said target circuits, and (ii) transmit the test output data from the first target circuit as test input data to a second of said target circuits;
a second target data path operable to: (i) receive test output data of the second target circuit, and (ii) transmit the test output data of the second target circuit as test input data to the first target circuit; and
at least two memories operable to transmit control data to the two target circuits, respectively.

39. The apparatus of claim 38, wherein the first and second target circuits are respective data memories.

40. The apparatus of claim 39, wherein the two memories are operable to transmit receive the test input data and transmit the test output data concurrently.

41. A method, comprising:
entering a scan mode by a test circuit within an integrated circuit;
scanning test input data into an input circuit of the test circuit;
entering an AC test mode by the test circuit;
directing a plurality of streams of the test input data toward a target by the test circuit;
generating test output data by the target;
transmitting test output data from the target to an output circuit;
transitioning from the AC test mode to the scan mode by the test circuit; and
scanning the test output data out of the output circuit.

42. An integrated circuit comprising:
a data flow controller operable to place a test circuit within the integrated circuit in a scan mode;
an input circuit within the test circuit operable to:
receive test input data in accordance with the scan mode, and
transmit a plurality of streams of the test input data out of the input circuit, wherein the data flow controller is operable to place the test circuit in an AC test mode prior to the transmitting step;
a target operable to:
receive the plurality of streams of input data,
generate test output data, and
transmit the test output data out of the target; and
an output circuit operable to:
receive the test output data from the target, and
scan the test output data out of the output circuit, wherein the data flow controller is operable to transition the test circuit from the AC test mode to the scan mode before the scanning step.

43. A test circuit comprising:
a first memory operable to store test input data;
an input circuit operable to:
receive the test input data from the first memory, and
transmit a plurality of streams of the test input data out of the input circuit;
at least one target operable to:
receive the streams of test input data;
generate test output data based on the test input data, and
transmit the test output data out of the target;
an output circuit operable to receive the test output data from the target, and
transmit the test output data out of the output circuit; and
a second memory operable to:
receive the test output data from the output circuit, and store the test output data,
wherein the input circuit comprises a plurality of data-latch scan chains disposed between the first memory and the target.

44. A method, comprising:
entering a scan mode by a test circuit;
scanning test input data from a first memory into an input circuit of the test circuit;
entering an AC test mode by the test circuit;
directing a plurality of streams of the test input data toward at least one target;
generating test output data by the at least one target in response to the test input data;
transmitting the test output data from the at least one target to an output circuit;
transitioning from the AC test mode to the scan mode by the test circuit; and
scanning the output test data from the output circuit into a second memory.
